(19) United States
(12) Patent Application Publication
(10) Pub. No.: US 2018/0088151 A1
(43) Pub. Date: Mar. 29, 2018

(54) PROBE FOR A SIGNAL ANALYZING DEVICE

(71) Applicant: Rohde & Schwarz GmbH & Co. KG, München (DE)

(72) Inventor: Barry Rowland, Gröbenzell (DE)

(21) Appl. No.: 15/276,947

(22) Filed: Sep. 27, 2016

(51) Int. Cl. G01R 13/02; G01R 1/067; G01R 35/00

(52) U.S. Cl. CPC G01R 13/0254; G01R 35/002; G01R 1/06788

(57) ABSTRACT

A probe connectable to a signal analyzing device, said probe comprising an integrated reference signal generator adapted to generate a reference signal applied to a probe sensing area of said probe; and an integrated measurement circuit adapted to measure a probe signal provided by said probe sensing area in response to the applied reference signal.

### FIELD OF THE INVENTION

The invention relates to a probe connectable to a signal analyzing device providing a built-in calibration and deskew means.

### BACKGROUND

Current probes can sense an electrical current flowing through a conductor and convert the sensed current into a voltage that can be viewed and measured by a signal analyzing device such as an oscilloscope. Conventional current probes need to undergo a timing adjustment or a deskew procedure so that the measured signals are properly time-aligned with other probe signals of the system. Accordingly, conventional probes require the use of an external calibration fixture. However, the use of a calibration fixture forming a separate piece of equipment is inconvenient and time-consuming for the user when performing measurements.

Accordingly, there is a need to provide a probe for a signal analyzing device having built-in calibration and deskew capabilities.

### SUMMARY OF THE INVENTION

The invention provides according to a first aspect a probe connectable to a signal analyzing device said probe comprising:

an integrated reference signal generator adapted to generate a reference signal applied to a probe sensing area of said probe and
an integrated measurement circuit adapted to measure a probe signal provided by said probe sensing area in response to the applied reference signal.

In a possible embodiment of the probe according to the first aspect of the present invention, the probe is a current probe comprising a current probe sensing area adapted to sense an electrical current flowing through an electrical line.

In a further possible embodiment of the probe according to the first aspect of the present invention, the current probe comprises a magnetic current probe sensing area.

In a possible embodiment of the probe according to the first aspect of the present invention, the magnetic current probe sensing area of the current probe comprises current measurement clamps, a Hall sensor and/or an AC/DC current measurement means.

In a still further possible embodiment of the probe according to the first aspect of the present invention, the reference signal generated by a reference signal generator of the current probe is applied to the current probe sensing area of the current probe through a looped calibration wire connected to the reference signal generator of the current probe.

In a further possible embodiment of the probe according to the first aspect of the present invention, the reference signal generator of the current probe is adapted to generate a calibration current applied to the looped calibration wire.

In a still further possible embodiment of the probe according to the first aspect of the present invention, the integrated reference signal generator of the current probe is adapted to generate a periodic pulsed calibration current applied as a first reference signal via the looped calibration wire to the current probe sensing area of the current probe.

In a still further possible embodiment of the probe according to the first aspect of the present invention, the current probe comprises a metallic landing pin adapted to be connected by a tip of a voltage probe sensing area of a separate voltage probe pressed against the landing pin.

In a still further possible embodiment of the probe according to the first aspect of the present invention, the reference signal generator of the current probe is adapted to generate a periodic pulsed calibration voltage applied as a second reference signal to the voltage probe sensing area of the voltage probe pressed against the landing pin of the current probe.

In a still further possible embodiment of the probe according to the first aspect of the present invention, the pulsed calibration current and the pulsed calibration voltage generated by the reference signal generator integrated in said current probe are time-aligned to each other.

In a still further possible embodiment of the probe according to the first aspect of the present invention, a current measurement circuit integrated in the current probe is adapted to measure a current probe signal provided by the current probe sensing area of the current probe in response to the pulsed calibration current applied as a first reference signal via the looped calibration wire to the current probe sensing area of the current probe and to supply the measured current probe signal to the signal analyzing device via a first cable connecting the current probe to a first port of the signal analyzing device.

In a still further possible embodiment of the probe according to the first aspect of the present invention, a voltage measurement circuit integrated in the voltage probe is adapted to measure a voltage probe signal provided by the voltage probe in response to the pulsed calibration voltage applied as a second reference signal via the landing pin of the current probe to the voltage probe sensing area of said voltage probe and to supply the measured voltage probe signal to the signal analyzing device via a second cable connecting the voltage probe to a second port of the signal analyzing device.

In a still further possible embodiment of the probe according to the first aspect of the present invention, the current probe signal measured in response to the pulsed calibration current and supplied by the current probe via the first cable to the first port of the signal analyzing device and the voltage probe signal measured in response to the pulsed calibration voltage and supplied by the voltage probe via the second cable to the second port of the signal analyzing device are compared by a probe skew determination unit of the signal analyzing device to determine automatically a probe skew between the connected current probe and the connected voltage probe.

In a further possible embodiment of the probe according to the first aspect of the present invention, the determined probe skew is automatically compensated by a skew compensation unit of the signal analyzing device.

In a still further possible embodiment of the probe according to the first aspect of the present invention, a calculation unit of the signal analyzing device is adapted to calculate an electrical power of a current probe signal received at the first port of the signal analyzing device and a voltage probe signal received at the second port of the signal analyzing device on the basis of the probe skew determined by the probe skew determination unit of the signal analyzing device.

In a still further possible embodiment of the probe according to the first aspect of the present invention, the probe comprises integrated signal conditioning means to process the analog probe signal provided by the probe sensing area of the probe supplied to the integrated measurement circuit of the probe.

The invention further provides according to a second aspect a current probe connectable to a signal analyzing device comprising:

an integrated reference signal generator adapted to generate a calibration current applied as a first reference signal to a current probe sensing area of the current probe and adapted to generate a calibration voltage applied as a second reference signal to a tip of a voltage probe sensing area of a voltage probe touching a landing pin of the current probe and comprising an integrated measurement circuit adapted to measure a current probe signal provided by the current probe sensing area of the current probe.

In a possible embodiment of the current probe according to the second aspect of the present invention, the calibration current is applied to a magnetic current probe sensing area of the current probe by means of a looped calibration wire connected to the reference signal generator integrated in the current probe.

The invention further provides according to a third aspect a signal analyzing device comprising

a first port adapted to connect a current probe to receive a current probe signal measured by the current probe in response to a calibration current generated by a reference signal generator integrated in the current probe;
a second port adapted to connect a voltage probe to receive a voltage probe signal measured by said voltage probe in response to a calibration voltage generated by the reference signal generator integrated in the current probe and applied to the voltage probe and
a probe skew determination unit adapted to determine automatically a probe skew between a current probe connected to the first port and a voltage probe connected to the second port of the signal analyzing device on the basis of the received current probe signal and the received voltage probe signal.

The invention further provides according to a fourth aspect a probe skew determination unit for a signal analyzing device wherein the probe skew determination unit is adapted to determine automatically a probe skew between a current probe connected to a first port of the signal analyzing device and a voltage probe connected to a second port of the signal analyzing device on the basis of the received current probe signal and the received voltage probe signal.

The invention further provides according to a further aspect a method for calibrating a probe connectable to a signal analyzing device, the method comprising the steps of:

applying a reference signal generated by a reference signal generator integrated in the probe to a probe sensing area of said probe,
measuring a probe signal generated by the probe sensing area of said probe in response to the applied reference signal by a measurement circuit of said probe and comparing the reference signal and the probe signal to calibrate said probe.

The invention further provides according to a further aspect a method for determining a probe skew between a current probe and a voltage probe, the method comprising the steps of:

providing a current probe signal measured by a current probe in response to a calibration current generated by a reference signal generator of the current probe,
providing a voltage probe signal measured by a voltage probe in response to a time-aligned calibration voltage generated by the reference signal generator of the current probe and applied to the voltage probe and
determining the probe skew between the current probe and the voltage probe on the basis of the provided current probe signal and the provided voltage probe signal.

### BRIEF DESCRIPTION OF FIGURES

In the following, different aspects of the present invention are described in more detail with reference to the enclosed figures.

FIG. 1 shows a block diagram of a possible exemplary embodiment of a probe according to a first aspect of the present invention;

FIG. 2 shows a schematic diagram for illustrating a possible exemplary embodiment of a current probe according to a further aspect of the present invention;

FIG. 3 shows a schematic diagram of a measurement setup comprising a signal analyzing device according to a further aspect of the present invention;

FIG. 4 shows a flowchart for illustrating a possible exemplary embodiment of a method for calibrating a probe according to a further aspect of the present invention;

FIG. 5 shows a further flowchart for illustrating a possible exemplary embodiment of a method for determining a probe skew between a current probe and a voltage probe according to a further aspect of the present invention.

### DETAILED DESCRIPTION OF EMBODIMENTS

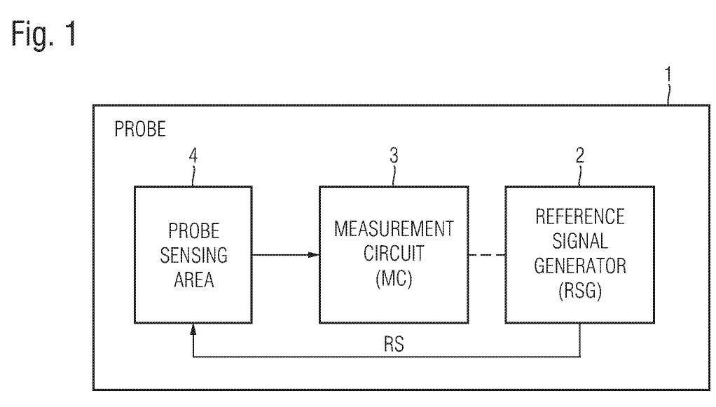

As can be seen in FIG. 1, a probe 1 according to the first aspect of the present invention comprises in the illustrated exemplary embodiment an integrated reference signal generator 2 and an integrated measurement circuit 3. The integrated measurement circuit 3 is adapted to measure a probe signal PS provided by a probe sensing area 4 in response to an applied reference signal. The integrated reference signal generator 2 of the probe 1 is adapted to generate the reference signal RS which is applied to the probe sensing area 4 of the probe 1. The integrated measurement circuit 3 is adapted to measure the probe signal PS provided by the probe sensing area 4 in response to the applied reference signal RS as illustrated in FIG. 1. The probe 1 as shown in FIG. 1 can be connected to a signal analyzing device. In a possible embodiment, the probe 1 can be connected to an oscilloscope.

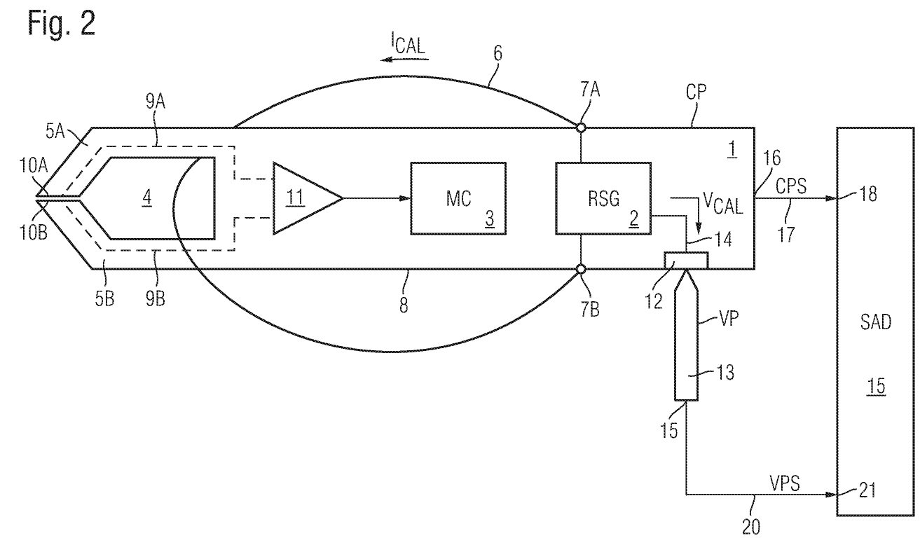

In a possible embodiment, the probe 1 as shown in FIG. 1 can be formed by a current probe as illustrated in FIG. 2. In the illustrated exemplary embodiment of FIG. 2, the current probe 1 comprises a current probe sensing area 4 defined by current measurement clamps 5A, 5B. In the illustrated embodiment, the reference signal generator 2 of said current probe 1 is integrated in a housing of the current probe 1 comprising the current measurement clamps 5A, 5B. The current probe 1 generates a reference signal which can be applied to the current probe signal sensing area 4 of the current probe 1 via a looped calibration wire connected to the reference signal generator 2 of the current probe 1. In the illustrated embodiment of FIG. 2, the calibration wire 6 is connected to two pins 7A, 7B of the current probe housing 8 being in electrical contact with the integrated reference signal generator 2. In a preferred embodiment, the calibration wire 6 is fixed to a first electrical pin 7A that can be removed from the second electrical pin 7B to be inserted through the magnetic current probe sensing area 4 defined by the two opposing current measurement clamps 5A, 5B of the current probe 1. In a possible embodiment, the reference signal generator 2 of the current probe 1 is adapted to generate a calibration current I_{CAL} applied to the looped calibration wire 6 and flowing through the current probe signal sensing area 4 of the current probe 1 as shown in FIG. 2. In a possible embodiment, the integrated reference signal generator 2 of the current probe 1 is adapted to generate a periodic pulsed calibration current applied as a first reference signal via the looped calibration wire 6 to the current probe sensing area 4 of the current probe 1. As shown in FIG. 2, electrical wires 9A, 9B extend through clamps 5A, 5B having tip portions 10A, 10B. When the two opposing clamps 5A, 5B are pressed against each other both tips 10A, 10B do touch each other and an electrical loop is closed by the integrated wires 9A, 9B forming a current probe sensing area 4 which is adapted to sense an electrical current flowing through an electrical line which can be formed by the looped calibration wire 6 as shown in FIG. 2. The electrical wires 9A, 9B integrated in the current measurement clamps 5A, 5B are connected to inputs of a driver circuit which can be formed by an operation amplifier 11 as shown in FIG. 2. The output of the driver circuit 11 is connected to the integrated measurement circuit 3. In a possible embodiment, the integrated reference signal generator 2 of the current probe 1 is adapted to generate a periodic pulsed calibration current I_{CAL} applied as a first reference signal via the looped calibration wire 6 to the current probe sensing area 4 of the current probe 1. The current probe 1 further comprises in the illustrated embodiment a metallic landing pin 12 connected by a tip of a voltage probe sensing area of a separate voltage probe 13 pressed against the landing pin 12 as shown in FIG. 2. The metallic landing pin 12 is connected to the integrated reference signal generator 2 via a signal line 14. The metallic landing pin 12 is integrated in the current probe housing 8 of the current probe 1. The reference signal generator 2 of the current probe 1 is adapted to generate a periodic pulsed calibration voltage V_{CAL} applied as a second reference signal to the voltage probe sensing area of the voltage probe 13 being pressed against the landing pin 12 of the current probe 1. The pulsed calibration current I_{CAL} and the pulsed calibration voltage V_{CAL} generated by the reference signal generator 2 integrated in the housing 8 of the current probe 1 are time-aligned to each other. The current measurement circuit 3 integrated in the housing 8 of the current probe 1 is adapted to measure a current probe signal CPS generated by the current probe sensing area 4 defined by the electrical loop wires 9A, 9B in response to the pulsed calibration current I_{CAL} applied as a first reference signal via the looped calibration wire 6 to the current probe sensing area 4 of the current probe 1.

The integrated measurement circuit 3 is adapted to supply the measured current probe signal CPS to a signal analyzing device 15 as shown in FIG. 2. The signal analyzing device 15 can be in a possible embodiment an oscilloscope. The current probe 1 comprises a first signal interface 16 connected via a first cable 17 to a first port 18 of the signal analyzing device 15. The integrated measurement circuit 3 of the current probe 1 is adapted to supply the measured current probe signal CPS to the signal analyzing device 15 via the first cable 17 connecting the current probe 1 to the first port 18 of the signal analyzing device 15. Further, a voltage measurement circuit integrated in the voltage probe 13 is adapted to measure a voltage probe signal VPS provided by the voltage probe sensing area of the voltage probe 13 in response to the pulsed calibration voltage V_{CAL} applied as a second reference signal via the landing pin 12 of the current probe 1 to the voltage probe sensing area at the tip portion of said voltage probe 13. The voltage probe 13 comprises a signal interface 19 connected via a second cable 20 to a second port 21 of the signal analyzing device 15. The voltage measurement circuit integrated in the voltage probe 13 is adapted to supply the measured voltage probe signal VPS to the signal analyzing device 15 via the second cable 20 connecting the voltage probe 13 to the second port 21 of the signal analyzing device 15. In a possible embodiment, a current probe signal CPS measured in response to the pulsed calibration current and supplied by the current probe 1 via the first cable 17 to the first port 18 of the signal analyzing device 15 and the voltage probe signal VPS measured in response to the pulsed calibration voltage and supplied by the voltage probe 13 via the second cable 20 to the second port 21 of the signal analyzing device 15 are compared by a probe skew determination unit of the signal analyzing device 15 to determine automatically a probe skew between the connected current probe 1 and the connected voltage probe 13. The cables 17, 20 can be shielded cables. In a possible embodiment, the determined probe skew can be automatically compensated by an integrated skew compensation unit of the signal analyzing device 15. In a further possible embodiment, the signal analyzing device 15 further comprises an integrated calculation unit which can be formed by a microprocessor. The calculation unit of the signal analyzing device 15 is adapted in a preferred embodiment to calculate an electrical power of the current probe signal CPS received at the first port 18 of the signal analyzing device 15 and a voltage probe signal VPS received at the second port 21 of the signal analyzing device 15 on the basis of the probe skew determined by the probe skew determination unit of the signal analyzing device 15. As shown in FIG. 2, the current probe can comprise integrated signal conditioning means to process the analog probe signal provided by the probe sensing area 4 of the current probe 1 supplied to the integrated measurement circuit 3 of the probe 1. The signal conditioning means can for instance comprise a signal amplifier 11 providing a time delay.

As can be seen in FIG. 2, the measurement setup having the probe 1 according to the first aspect of the present invention allows a timing adjustment or deskewing without using any external calibration fixture. In the illustrated measurement setup, a calibration current I_{CAL} can be generated to adjust a gain of the probe channel or probe as required. Further, the probe 1 according to the first aspect of the present invention does comprise a calibration current source and a calibration voltage source integrated in the body or housing 8 of the current probe 1. The reference signal generator 2 comprises in the illustrated embodiment an integrated current source for providing a calibration current I_{CAL} and an integrated voltage source for providing a calibration voltage V_{CAL}. In a possible implementation, the reference signal generator 2 comprises an integrated calibration current source adapted to generate a periodic pulsed calibration current which can be applied as a first reference signal via the looped calibration wire 6 to the current probe sensing area 4 of the current probe 1. Further, the reference signal generator 2 comprises in a possible embodiment an integrated calibration voltage source adapted to generate a periodic pulsed calibration voltage applied as a second reference signal via the landing pin 12 to the voltage probe sensing area of the voltage probe 13. In the illustrated embodiment of FIG. 2, the calibration current is applied through the looped wire 6 inserted into a magnetic sensing area 4 of the current probe 1.

In an alternative embodiment, the current probe 1 may also comprise a Hall sensor as a magnetic current probe sensing area 4. In a still further possible alternative embodiment, the magnetic current probe 4 may also comprise AC/DC current measurement means. Further, the sensing area may comprise a sensor resistor in case of a differential input voltage current probe type. The current carrying wire 6 adapted to carry the calibration current I_{CAL} generated by the reference signal generator 2 can take the form of a ground lead and may be connected to the current pin 7B of the housing 8 of the current probe 1. The wire 6 can be easily inserted into the current sensing area 4 of the magnetic current probe 1 as shown in FIG. 2. Further, the housing 8 of the current probe 1 can comprise a probe point or metallic landing pin provided for connection of a voltage probe 13. A voltage pulse is provided that can be precisely time-aligned to the current calibration pulsed edge of the periodic pulsed calibration current.

In a preferred embodiment, the reference signal generator 2 comprises in a possible implementation a pulsed timing circuitry which can be activated automatically when the pin voltage goes to near ground voltage, in particular when the looped wire 6 is connected between the current outpin 7A and ground pin 7B. The current probe 1 as illustrated in the embodiment of FIG. 2 allows a self-contained calibration which can form part of a probe calibration process.

According to an aspect of the present invention, a current probe 1 is provided being connectable to a signal analyzing device 15 wherein the current probe 1 comprises an integrated reference signal generator 2 and an integrated measurement circuit 3. The integrated reference signal generator 2 is adapted to generate a calibration current applied as a first reference signal to a current probe sensing area 4 of the current probe 1 and is further adapted to generate a calibration voltage applied as a second reference signal to a tip of a voltage probe sensing area of a voltage probe 13 touching a landing pin 12 of the current probe 1. The integrated measurement circuit 3 of the current probe 1 is adapted to measure the current probe signal CPS provided by the current probe sensing area 4 of the current probe 1. The calibration current generated by the reference signal generator 2 is applied to a magnetic current probe sensing area 4 of the current probe 1 by means of the looped calibration wire 6 which is connected to the reference signal generator 2 integrated in the current probe 1.

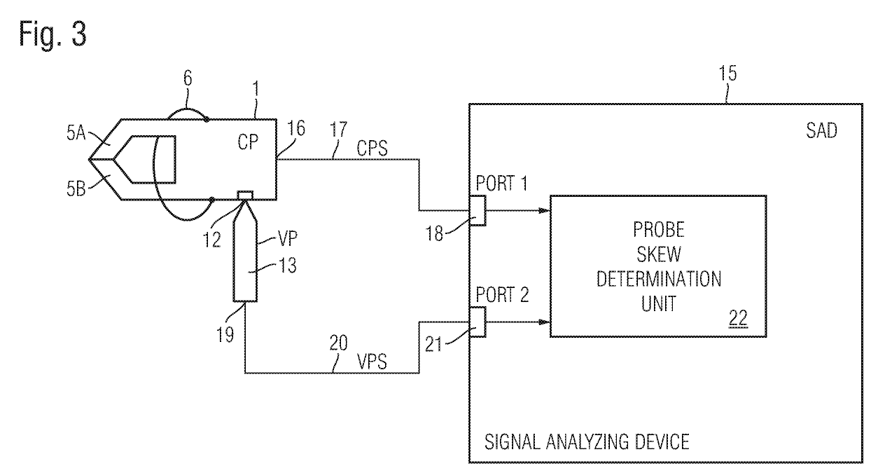

FIG. 3 shows a schematic diagram for illustrating a signal analyzing device 15 according to a further aspect of the present invention. In the illustrated embodiment, the signal analyzing device 15 comprises a first port 18 and a second port 21. The first port 18 of the signal analyzing device 15 is adapted to connect a current probe 1 according to the first aspect of the present invention with the signal analyzing device 15. The second port 21 of the signal analyzing device 15 is adapted to connect a voltage probe 13 to the signal analyzing device 15. The first port 18 is adapted to receive a current probe signal CPS measured by the attached current probe 1 in response to a calibration current I_{CAL} generated by the reference signal generator 2 integrated in the current probe 1. The second port 21 of the signal analyzing device 15 is adapted to receive a voltage probe signal VPS measured by the voltage probe 13 in response to a calibration voltage V_{CAL} generated by the reference signal generator 2 integrated in the current probe 1 and applied through the landing pin 12 to a tip of the voltage probe 13. The signal analyzing device 15 comprises in the illustrated embodiment a probe skew determination unit 22 adapted to determine automatically a probe skew between a current probe 1 connected to the first port 18 and a voltage probe 13 connected to the second port 21 of the signal analyzing device 15 on the basis of the received current probe signal CPS and the received voltage probe signal VPS. In a possible embodiment, the current probe signal CPS and the voltage probe signal VPS are compared by the probe skew determination unit 22 of the signal analyzing device 15 to determine automatically a probe skew between the connected current probe 1 and the connected voltage probe 13. In a further possible embodiment of the signal analyzing device 15 as shown in FIG. 3, the signal analyzing device 15 further comprises a skew compensation unit. In a possible embodiment, the probe skew determined by the probe skew determination unit 22 is automatically compensated by the skew compensation unit of the signal analyzing device 15. In a still further possible embodiment of the signal analyzing device 15, the signal analyzing device 15 comprises a calculation unit which is adapted to calculate automatically an electrical power of the current probe signal CPS received at the first port 18 of the signal analyzing device 15 and the voltage probe signal VPS received at the second port 21 of the signal analyzing device 15 on the basis of the probe skew determined by the probe skew determination unit 22 of the signal analyzing device 15.

In the illustrated embodiment of FIG. 3, the probe skew determination unit 22 is integrated in the signal analyzing device 15. In a still further possible embodiment, the probe skew determination unit 22 can be integrated in an adapter device between connecting cables 17, 20 and the ports 18, 21 of the signal analyzing device 15. The invention provides according to a further aspect, a probe skew determination unit 22 of a signal analyzing device 15 which can be integrated in a signal adapter attached to the signal analyzing device 15. In this embodiment, the probe skew determination unit 22 is integrated in the housing of an adapter device connectable to input ports 18, 21 of the signal analyzing device 15. The probe skew determination unit 22 integrated in the adapter device can determine automatically a probe skew between a current probe 1 and a voltage probe 13 connected to the adapter and provide information about the determined probe skew to the signal analyzing device for further processing. The signal analyzing device 15 can for instance perform an automatic compensation of the determined probe skew.

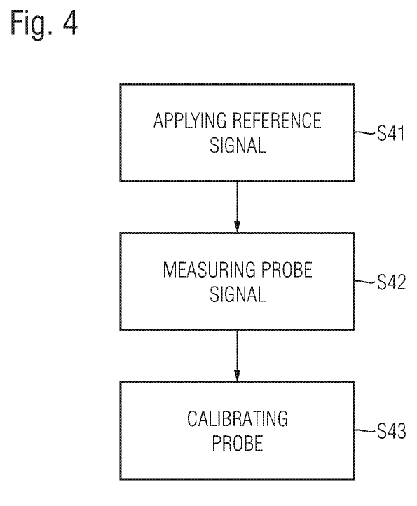

FIG. 4 shows a flowchart of a possible exemplary embodiment of a method for calibrating a probe 1 connected to a signal analyzing device 15 according to a further aspect of the present invention. In the illustrated flowchart of FIG. 4, in a first step S41, a reference signal is generated by a reference signal generator 2 integrated in the probe 1 and applied to a probe sensing area of the probe 1. In a further step S42, the probe signal generated by the probe sensing area of the probe 1 is measured in response to the applied reference signal by a measurement circuit 3 of the respective probe 1. Finally, the applied reference signal and the measured probe signal are compared in step S43 to calibrate automatically the probe 1.

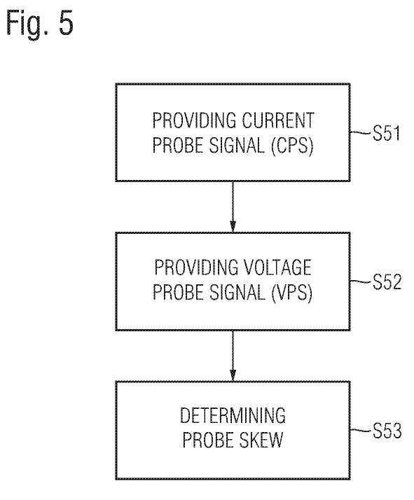

FIG. 5 shows a flowchart of a possible exemplary embodiment of a method for determining a probe skew between a current probe 1 and a voltage probe 13 according to a further aspect of the present invention. In the illustrated embodiment, in a first step S51, a current probe signal CPS measured by a current probe 1 in response to a calibration current generated by a reference signal generator 2 of the current probe 1 is provided. In a further step S52, a voltage probe signal VPS measured by a voltage probe 13 in response to a time-aligned calibration voltage generated by the reference signal 2 of the current probe 1 and applied to the voltage probe 13 is provided.

Finally, in step S53, a probe skew between the current probe 1 and the voltage probe 13 is determined automatically on the basis of the provided current probe signal CPS and the provided voltage probe signal VPS. The probe skew indicates a magnitude of a time difference between two events that ideally would occur simultaneously and can express jitter as the time deviation of a controlled edge from its nominal position. The probe skew determined in step S53 is in a possible embodiment automatically compensated by a skew compensation unit which can be integrated in a signal analyzing device 15 such as an oscilloscope. Further, the probe skew determined in step S53 can be used to calculate an electrical power of a current probe signal CPS received at a first port of a signal analyzing device 15 and a voltage probe signal VPS received at a second port of a signal analyzing device 15.

In a possible embodiment, the probe 1 comprises an integrated power source for the integrated circuits including the driver circuit 11, the measurement circuit 3 and the reference signal generator 2. The power source can comprise an insertable battery. In an alternative embodiment, the probe 1 is supplied with electrical power by the signal analyzing device 15 via cable 17. In a further possible implementation, the tip of the voltage probe can be fixed temporarily to the landing pin 12 during the calibration process, e.g. by screwing a tip thread into a fitting thread of the landing pin 12. The determined probe skew can be displayed on a display unit of the signal analyzing device 15 and/or on a display of the current probe 1.

What is claimed is:

1. A probe connectable to a signal analyzing device, said probe comprising:
an integrated reference signal generator adapted to generate a reference signal applied to a probe sensing area of said probe; and
an integrated measurement circuit adapted to measure a probe signal provided by said probe sensing area in response to the applied reference signal.

2. The probe according to claim 1 wherein the probe is a current probe comprising a current probe sensing area adapted to sense an electrical current flowing through an electrical line.

3. The probe according to claim 2 wherein said current probe comprises a magnetic current probe sensing area comprising current measurement clamps, a Hall sensor and/or AC/DC current measurement means.

4. The probe according to claim 2 wherein the reference signal generated by a reference signal generator of said current probe is applied to the current probe signal sensing area of said current probe through a looped calibration wire connected to the reference signal generator of said current probe.

5. The probe according to claim 4 wherein the reference signal generator of said current probe is adapted to generate a calibration current applied to said looped calibration wire.

6. The probe according to claim 5 wherein the integrated reference signal generator of said current probe is adapted to generate a periodic pulsed calibration current applied as a first reference signal via said looped calibration wire to the current probe sensing area of said current probe.

7. The probe according to claim 2 wherein the current probe comprises a metallic landing pin adapted to be connected by a tip of a voltage probe sensing area of a separate voltage probe pressed against said landing pin.

8. The probe according to claim 7 wherein the reference signal generator of said current probe is adapted to generate a periodic pulsed calibration voltage applied as a second reference signal to the voltage probe sensing area of the voltage probe pressed against the landing pin of said current probe.

9. The probe according to claim 8 wherein the pulsed calibration current and the pulsed calibration voltage generated by the reference signal generator integrated in said current probe are time-aligned to each other.

10. The probe according to claim 9 wherein a current measurement circuit integrated in said current probe is adapted to measure a current probe signal provided by said current probe sensing area of said current probe in response to the pulsed calibration current applied as a first reference signal via said looped calibration wire to the current probe sensing area of said current probe and to supply the measured current probe signal to the signal analyzing device via a first cable connecting said current probe to a first port of said signal analyzing device.

11. The probe according to claim 10 wherein a voltage measurement circuit integrated in said voltage probe is adapted to measure a voltage probe signal provided by said voltage probe sensing area of said voltage probe in response to the pulsed calibration voltage applied as a second reference signal via the landing pin of said current probe to said voltage probe sensing area of said voltage probe and to supply the measured voltage probe signal to the signal analyzing device via a second cable connecting said voltage probe to a second port of said signal analyzing device.

12. The probe according to claim 11 wherein the current probe signal measured in response to the pulsed calibration current and supplied by said current probe via the first cable to the first port of said signal analyzing device and the voltage probe signal measured in response to the pulsed calibration voltage and supplied by said voltage probe via the second cable to the second port of said signal analyzing device are compared by a probe skew determination unit of said signal analyzing device to determine automatically a probe skew between the connected current probe and the connected voltage probe.

13. The probe according to claim 12 wherein the determined probe skew is automatically compensated by a skew compensation unit of said signal analyzing device.

14. The probe according to claim 12 wherein a calculation unit of said signal analyzing device is adapted to calculate an electrical power of a current probe signal received at the first port of said signal analyzing device and a voltage probe signal received at the second port of said signal analyzing device on the basis of the probe skew determined by the probe skew determination unit of said signal analyzing device.

15. The probe according to claim 1 wherein the probe comprises integrated signal conditioning means to process the analog probe signal provided by the probe sensing area of said probe supplied to said integrated measurement circuit of said probe.

16. A current probe connectable to a signal analyzing device comprising:
an integrated reference signal generator adapted to generate a calibration current applied as a first reference signal to a current probe sensing area of said current probe and adapted to generate a calibration voltage applied as a second reference signal to a tip of a voltage probe sensing area of a voltage probe touching a landing pin of said current probe; and
an integrated measurement circuit adapted to measure a current probe signal provided by the current probe sensing area of said current probe.

17. The current probe according to claim 16 wherein said calibration current is applied to a magnetic current probe sensing area of said current probe by means of a looped calibration wire connected to the reference signal generator integrated in said current probe.

18. A signal analyzing device comprising:
a first port adapted to connect a current probe to receive a current probe signal measured by said current probe in response to a calibration current generated by a reference signal generator integrated in said current probe;
a second port adapted to connect a voltage probe to receive a voltage probe signal measured by said voltage probe in response to a calibration voltage generated by the reference signal generator integrated in said current probe and applied to said voltage probe; and
a probe skew determination unit adapted to determine automatically a probe skew between a current probe connected to the first port and a voltage probe connected to the second port of said signal analyzing device on the basis of the received current probe signal and the received voltage probe signal.

19. A method for calibrating a probe connectable to a signal analyzing device, the method comprising the steps of:
applying a reference signal generated by a reference signal generator integrated in said probe to a probe sensing area of said probe;
measuring a probe signal generated by the probe sensing area of said probe in response to the applied reference signal by a measurement circuit of said probe; and
comparing the reference signal and the probe signal to calibrate said probe.

20. A method for determining a probe skew between a current probe and a voltage probe, the method comprising the steps of:
providing a current probe signal measured by a current probe in response to a calibration current generated by a reference signal generator of said current probe;
providing a voltage probe signal measured by a voltage probe in response to a time-aligned calibration voltage generated by the reference signal generator of said current probe and applied to the voltage probe; and
determining the probe skew between the current probe and the voltage probe on the basis of the provided current probe signal and the provided voltage probe signal.
